(19) United States
(12) Patent Application Publication
(10) Pub. No.: US 2012/0162944 A1
(43) Pub. Date: Jun. 28, 2012

(54) METHOD FOR CONNECTING HOUSING PARTS

(75) Inventor: Helmut Brantsch, Ingolstadt (DE)

(73) Assignee: CONTINENTAL AUTOMOTIVE GMBH, Hannover (DE)

(21) Appl. No.: 13/392,160

(22) PCT Filed: Aug. 23, 2010
(86) PCT No.: PCT/EP2010/062270

§ 371 Date: Feb. 24, 2012

(30) Foreign Application Priority Data
Sep. 10, 2009 (DE) 10 2009 040 915.7

(51) Int. Cl. H05K 5/02; B23P 11/00

(52) U.S. Cl. 361/759; 29/428

(57) ABSTRACT

A method for connecting housing parts includes fixing at least two housing parts, with a circuit board to be disposed between the housing parts. The housing parts are fixed in contact with each other at least at the edge regions thereof, and the housing parts are connected in partial regions of the edge regions thereof by way of clinching.

The invention relates to a method for connecting housing parts.

In addition, the invention relates to a housing.

The invention also relates to an electronic component.

Furthermore, the invention relates to a vehicle.

Modern motor vehicles form complex systems of hardware and software. In such systems, a wide variety of electronic components are used. These components can be accommodated, inter alia, in housings in order to insert and replace them as desired in a modular fashion. These housings may be composed of multiple parts. Previous housing parts have been connected, for example, by screwing or flanging. Flanging is understood to be bending the edge of round or oval pieces of sheet metal at a right angle with a flanging machine or by hand. These methods are complex and also require a certain quantity of material, making the housings larger.

The invention is based on the object of connecting housing parts in a simple way which provides a saving in terms of material and space.

This object is achieved by means of the subject matter of the independent patent claims. Advantageous embodiments of the present invention are described in the dependent claims.

According to a first aspect of the invention, a method is made available for connecting housing parts, wherein the method comprises securing at least two housing parts, wherein a printed circuit board can be arranged between the housing parts, wherein the housing parts are secured one on top of the other at least in their edge regions, and connecting the housing parts in partial regions of their edge regions by means of clinching.

According to another aspect of the invention, a housing is made available, wherein the housing has at least two housing parts which are configured in such a way that a printed circuit board can be arranged between them, and wherein the housing parts can be connected at least in partial regions of their edge regions by means of clinching.

According to yet another aspect of the invention, an electronic component is provided that has the housing described above and a printed circuit board.

According to a further aspect of the invention, a vehicle having the described electronic component is made available.

According to one exemplary embodiment of the invention, a method for connecting housing parts is provided. In this method, at least two housing parts are secured, wherein a printed circuit board can be arranged between the housing parts, and wherein the housing parts are secured one on top of the other at least in their edge regions, and the housing parts are connected in partial regions of their edge regions by means of clinching.

Clinching is understood to mean a method for connecting pieces of sheet metal without using an additional material. It can be considered to be a joining method as well as a shaping method since the connection is brought about by shaping the material. The German term Durchsetzfügen [clinching] is also referred to as Clinchen. An advantage of clinching is that a pre-punching process is not carried out. The structural stability values can be in the region from approximately ⅔ up to 1.5 times a comparable spot welded connection. The fatigue resistance is higher than in the case of spot welded connections by virtue of the absence of a notch effect (in non-cutting connections) and because a thermal influence zone is not present. Clinching provides great potential in particular if different thicknesses of sheet metal have to be connected. If the “thick into thin” joining direction is maintained, structural stability values which exceed one and a half times the stability of a spot welded connection are possible. A further advantage is that different types of materials and/or coated pieces of sheet metal can also be joined.

As a result of at least partial regions of the housing parts being placed one on top of the other with a printed circuit board arranged therebetween, the printed circuit board can be secured in a perpendicular direction without play. Furthermore, expansion possibilities can be provided in the horizontal direction.

A further advantage can be that the housing connection does not experience rebounding due to plastic deformation. The slider which is often used on the die plate for clinching can be dispensed with.

In comparison with other known methods such as flanging or tox clinching, with this method a relatively small, space-saving and compact form of housing is required for the connection.

In the text which follows, preferred embodiments of the method are described. These also apply to the housing, to the electronic component and to the vehicle.

The housing parts can have corners and can be connected at the corners by means of clinching. The connection at the corners can ensure a good degree of stability of the connection. If the corners are connected in two directions by means of clinching, it is also possible to provide a play-free securing means in the horizontal direction.

The housing parts can have edges and be connected at least in partial regions of the edges by means of clinching. By means of the connection at the edges it is also possible to achieve a good degree of stability of the connection. Furthermore, a combination in which the housing parts are connected to one another both at the corners and in partial regions of the edges is possible.

In the text which follows, preferred embodiments of the housing are described. These also apply to the method, to the electronic component and to the vehicle.

The housing parts may be rectangular. In this way they are particularly well suited for holding a rectangular printed circuit board.

At least one housing part can be constructed with a bulge in a central region in order to accommodate the printed circuit board. As a result of this bulge the printed circuit board can easily be accommodated. The housing parts can also have a cutout through which a plug can be connected to the printed circuit board.

The housing parts can have corners and be connected at the corners by means of clinching. Furthermore, the housing parts can have edges and be connected at least in partial regions of the edges by clinching. In this way it is possible to achieve a good degree of stability and durability of the connection. Furthermore, a combination of connections at corners and edges is possible.

In the text which follows, preferred embodiments of the electronic component are described. They also apply to the method, to the housing and to the vehicle.

The electronic component can be any desired device which requires screening against electromagnetic irradiation and emissions (EMV, EMC, EMI, . . . ) and/or metal housings for conducting away dissipated power/heat. In particular, the electronic component can be a DC/DC converter. A DC/DC converter converts a constant input voltage through periodic switching, with the result that on arithmetic average another voltage value is produced at the output. This is frequently required in drive systems.

The housing can be a sheet-metal housing. A sheet-metal housing can be used for screening.

In the text which follows, additional refinements of the vehicle are described. They also apply to the housing, to the method and to the electronic component.

The vehicle can be, for example, an automobile (for example a motor vehicle, in particular a passenger car or a truck). However, it is also possible for the electronic component according to the invention to be implemented in a train, in an aircraft (for example an airplane, a helicopter or an airship) or in a ship.

It is to be noted that embodiments of the invention have been described with respect to different inventive subject matter. In particular, a number of embodiments of the invention are described with device claims and other embodiments of the invention are described with method claims. However, on reading this application it will become immediately clear to a person skilled in the art that unless explicitly specified otherwise, in addition to a combination of features which are associated with one type of inventive subject matter any desired combination of features which are associated with different types of inventive subject matter is also possible.

Further advantages and features of the present invention emerge from the following exemplary description of currently preferred embodiments. The individual figures of the drawing of this application can be considered merely to be schematic and not true to scale.

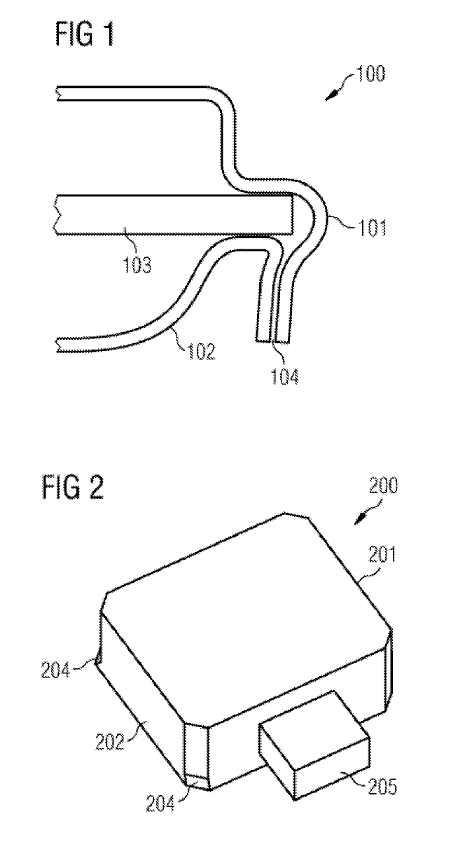

FIG. 1 shows a schematic design of a part of the housing according to an exemplary embodiment of the invention which is connected by means of clinching,

FIG. 2 shows a schematic view of a housing according to an exemplary embodiment of the invention,

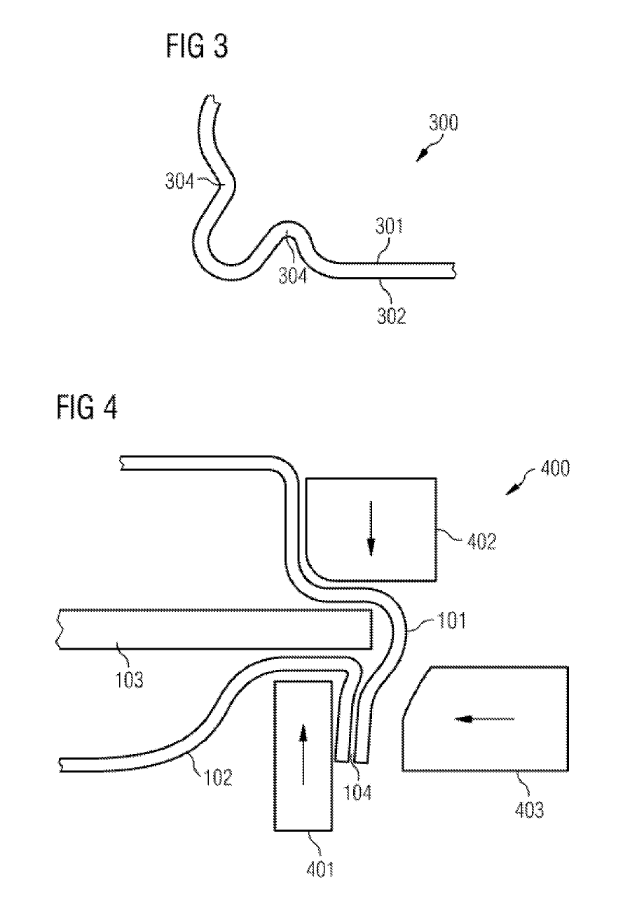

FIG. 3 shows a schematic partial view of a housing according to an exemplary embodiment of the invention, and

FIG. 4 shows a schematic design of a part of the housing which is connected by means of clinching, with tools.

The illustrations in the figures are schematic and not to scale. Identical or similar components in different figures are provided with identical reference symbols.

FIG. 1 shows a schematic design of a part of the housing 100 according to an exemplary embodiment of the invention which is connected by means of clinching. Here, a first housing part 101 is arranged on a second housing part 102. A printed circuit board 103 is arranged between the two housing parts. The two housing parts 101 and 102 are connected in a partial region 104 of their edge regions by means of clinching. In this context, the printed circuit board 103 is secured between the two housing parts 101 and 102. In this way, the printed circuit board can be secured without play between the housing parts.

FIG. 2 shows a schematic view of a housing 200 according to an exemplary embodiment of the invention. The housing 200 has a first housing part 201 and a second housing part 202. The two housing parts are connected at the corners by means of clinching. A printed circuit board, which can be accessed via a plug 205 which is arranged in a cutout in the housing 200, is arranged within the housing.

FIG. 3 shows a schematic partial view of a housing 300 according to an exemplary embodiment of the invention. In this context, a first housing part 301 and a second housing part 302 are connected to one another at a corner by means of clinching. In this case, the housing parts are connected to one another at the corner at two locations 204 by means of clinching. In this way, the printed circuit board can be satisfactorily secured.

FIG. 4 shows a further exemplary embodiment of the invention with a schematic design 400 of a part 100 of the housing which is connected by means of clinching, as in FIG. 1, wherein in addition the tools 401, 402, 403 for clinching are represented. The tools are in particular a die plate 401, a retaining element 402 and a compression die 403. Instead of a retaining element 402 it is also optionally possible to use a clamp. The housing parts 101 and 102 are clamped in between the retaining element 402 and the die plate 401. In this context, the printed circuit board 103 is secured between the two housing parts 101 and 102. In this way, the printed circuit board can be secured without play between the housing parts. It is also conceivable to secure the housing parts 101, 102 without a printed circuit board 103. After the housing parts 101, 102 are clamped in between the retaining element 402 and the die plate 401, the two housing parts 101, 102 which are clamped together are deformed in a partial region 104 by the compression die 403. In a part of the partial region 104 at which the compression die 104 acts perpendicularly on the die plate 401, the housing parts 101, 102 are additionally pressed or stamped one against the other, ideally in a positively locking fashion. It is also conceivable that the compression die 403 has an impression in the pressing direction. Likewise, the die plate 401 can have a structure on the surface which counteracts the compression die 403 in the pressing direction, with the result that when the housing parts 101, 102 are pressed one against the other an impression is formed in the partial region 104. As a result an improved connection of the housing parts 101, 102 is brought about. The die plate 401 is formed without an undercut. This has the advantage that there is no need for an additional slider to remove the die plate 401. It is to be noted that the embodiments which are described here merely constitute a limited selection of possible embodiment variants of the invention. It is therefore possible to combine the features of individual embodiments with one another in a suitable way, with the result that the person skilled in the art is to consider that a large number of various embodiments are disclosed as obvious with the embodiment variants which are explicit here.

1-12. (canceled)

13. A method for connecting housing parts, the method comprising the following steps:
providing at least two housing parts with edge regions;
securing the at least two housing parts, wherein a printed circuit board can be disposed between the housing parts, with the housing parts lying on top of one another at least in the edge regions thereof; and
clinching partial regions of the edge regions of the housing parts for connecting the housing parts.

14. The method according to claim 13, wherein the housing parts have corners and the method comprises connecting the housing parts at the corners by way of clinching.

15. The method according to claim 13, wherein the housing parts have edges and the method comprises connecting the housing parts at least in partial regions of the edges by way of clinching.

16. A housing, comprising:
at least two housing parts configured for placement of a printed circuit board between said at least two housing parts, said housing parts having edge regions and being connected at least in partial regions of said edge regions by a clinching connection.

17. The housing according to claim 16, wherein said housing parts are rectangular.

18. The housing according to claim 16, wherein at least one of said housing parts is formed with a bulge in a central region thereof for accommodating therein the printed circuit board.

19. The housing according to claim 16, wherein said housing parts have corners and said housing parts are connected to one another at said corners by way of clinching.

20. The housing according to claim 16, wherein said housing parts have edges and said housing parts are connected at least in partial regions of said edges by clinching.

21. An electronic component, comprising a housing according to claim 16 and a printed circuit board disposed in said housing.

22. The electronic component according to claim 21, configured as a DC/DC converter.

23. The electronic component according to claim 21, wherein said housing is a sheet-metal housing.

24. A vehicle, comprising an electronic component according to claim 21.
